(19) United States
(12) Patent Application Publication
(10) Pub. No.: US 2022/0261559 A1
(43) Pub. Date: Aug. 18, 2022

(54) ARITHMETIC CIRCUIT AND NEUROMORPHIC DEVICE

(71) Applicant: TDK CORPORATION, Tokyo (JP)

(72) Inventors: Tatsuo SHIBATA, Tokyo (JP); Yukio TERASAKI, Tokyo (JP)

(73) Assignee: TDK CORPORATION, Tokyo (JP)

(21) Appl. No.: 17/627,027

(22) PCT Filed: Feb. 27, 2020
(86) PCT No.: PCT/JP2020/008025

§ 371 Date: Jan. 13, 2022

(51) Int. Cl. G06G 7/60; G06N 3/063; G06F 7/544

(52) U.S. Cl. CPC G06G 7/60; G06F 7/5443; G06N 3/0635

(57) ABSTRACT

An arithmetic circuit includes a variable resistance element having three terminals of a first terminal, a second terminal, and a third terminal and configured such that the resistance value is variable, an input line connected to the first terminal, a capacitor connected to the second terminal and provided between the second terminal and the reference potential, a first switching element connected to the third terminal, a wiring connected to the third terminal through the first switching element, a second switching element connected to a first end of the wiring, and a third switching element connected to a second end of the wiring.

### TECHNICAL FIELD

The present invention relates to an arithmetic circuit and a neuromorphic device.

### BACKGROUND ART

Research and development of nervous system models are being carried out for the purpose of improving the power performance of a neuromorphic device that performs neural network calculations. Such a nervous system model may include a spiking neural network (SNN) or the like.

As a method for implementing a spiking neural network, a method for implementing the spiking neural network using a two terminal variable resistance element is known (see Patent Document 1). Here, the variable resistance element is a two terminal element capable of changing resistance, and is, for example, a phase change memory (PCM) or the like.

### CITATION LIST

### Patent Document

### [Patent Document 1]

Published Japanese Translation No. 2018-508922 of the PCT International Publication

### SUMMARY OF INVENTION

### Technical Problem

Here, in the related art, a method for implementing a spiking neural network using a three terminal variable resistance element has not been known.

### Solution to Problem

An object of the present invention is to provide an arithmetic circuit including a variable resistance element having three terminals of a first terminal, a second terminal, and a third terminal and configured such that a resistance value is variable, an input line connected to the first terminal, a capacitor connected to the second terminal and provided between the second terminal and a reference potential, a first switching element connected to the third terminal, a wiring connected to the third terminal through the first switching element, a second switching element connected to a first end of the wiring, and a third switching element connected to a second end of the wiring.

### Advantageous Effects of Invention

According to the present invention, an arithmetic circuit and a neuromorphic device capable of implementing a spiking neural network using a three terminal variable resistance element can be provided.

### BRIEF DESCRIPTION OF DRAWINGS

FIG. 1 is a diagram showing an example of the smallest unit of an arithmetic circuit according to a first embodiment.

FIG. 2 is a diagram showing an example of a neuromorphic device according to the first embodiment.

FIG. 3 is a diagram showing an example of a waveform of a signal output from a third terminal in the arithmetic circuit.

FIG. 4 is a diagram showing another example of the waveform of the signal output from the third terminal in the arithmetic circuit.

FIG. 5 is a diagram showing still another example of the waveform of the signal output from the third terminal in the arithmetic circuit.

FIG. 6 is a timing chart showing an example of temporal changes in voltages in a plurality of units connected to one wiring of the arithmetic circuit.

FIG. 7 is a timing chart showing an example of temporal changes in voltages in the plurality of units connected to one wiring of the arithmetic circuit.

FIG. 8 is a diagram showing an example of a variable resistance element according to the first embodiment.

FIG. 9 is a diagram showing an example of an arithmetic circuit 1 built on a substrate.

### DESCRIPTION OF EMBODIMENTS

### First Embodiment

Hereinafter, the present embodiment will be described in detail with reference to the drawings as appropriate. The drawings used for the following description may show feature portions in an enlarged scale for convenience in order to facilitate an understanding of features, and the dimensional ratio or the like of each constituent element may be different from the actual one. Materials, dimensions, and the like provided in the following description are exemplary examples, and the present invention is not limited thereto, and can be appropriately modified and implemented within the range in which effects of the present invention are exhibited.

### <Arithmetic Circuit>

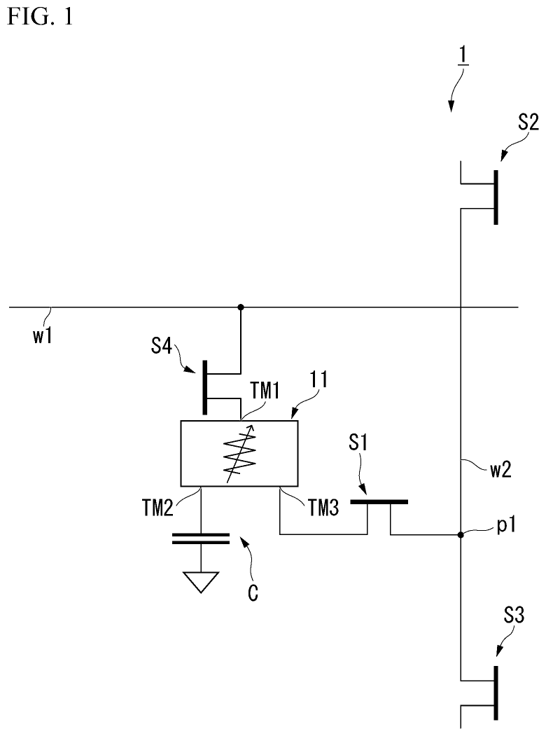

FIG. 1 is a diagram showing an example of the smallest unit of an arithmetic circuit according to a first embodiment.

An arithmetic circuit 1 outputs a spike signal of a spiking neural network. The arithmetic circuit 1 includes, for example, a variable resistance element 11, an input line w1, a wiring w2, a first switching element S1, a second switching element S2, a third switching element S3, a fourth switching element S4, and a capacitor C.

The variable resistance element 11 is an element capable of changing resistance. Furthermore, the variable resistance element 11 has three terminals including a first terminal TM1, a second terminal TM2, and a third terminal TM3. That is, the variable resistance element 11 is a three terminal element. The variable resistance element 11 is, for example, a magnetic domain wall motion element. The magnetic domain wall motion element is a magnetic domain wall motion type magnetoresistance effect element, and details will be described later. The variable resistance element is not limited to the magnetic domain wall motion element, and may be another three terminal variable resistance element.

The input line w1 is a transmission line through which an input signal is transmitted. The wiring w2 is a transmission line through which a charging signal and an output signal are transmitted. The transmission line may be a metal wiring provided on a semiconductor integrated circuit, a conductor printed on a substrate, or a linearly provided copper wire. The input line w1 is connected to the first terminal TM1 of the variable resistance element 11. The input line w1 is connected to the first terminal TM1. The wiring w2 is connected to the third terminal TM3 through the first switching element S1.

The first switching element S1, the second switching element S2, the third switching element S3, and the fourth switching element S4 are switching elements that control the flow of current. When the switching element becomes an ON state, the switching element becomes a conducting state to be electrically connected. When the switching element becomes an OFF state, the switching element becomes a disconnected state to be electrically disconnected. The switching element is, for example, a field effect transistor, a bipolar transistor, an ovonic threshold switch, or the like. Hereinafter, the switching element will be described based on an example of a field effect transistor.

The first switching element S1 is connected between the third terminal TM3 and the wiring w2. For example, a source of the first switching element S1 is connected to the third terminal TM3, a drain of the first switching element S1 is connected to the wiring w2, and a gate of the first switching element S1 is connected to a control unit 20 described later.

The second switching element S2 is connected to a first end of the wiring w2. For example, a source of the second switching element S2 is connected to a charging circuit 13 described later, a drain of the second switching element S2 is connected to the wiring w2, and a gate of the second switching element S2 is connected to the control unit 20 described later.

The third switching element S3 is connected to a second end of the wiring w2. For example, a source of the third switching element S3 is connected to the wiring w2, a drain of the third switching element S3 is connected to an output circuit 14 described later, and a gate of the third switching element S3 is connected to the control unit 20 described later.

The fourth switching element S4 is connected between the input line w1 and the first terminal TM1. For example, a source of the fourth switching element S4 is connected to the input line w1, a drain of the fourth switching element S4 is connected to the first terminal TM1, and a gate of the fourth switching element S4 is connected to the control unit 20 described later. The fourth switching element S4 may be omitted. In addition, a resistor may be provided in place of the fourth switching element S4.

The capacitor C is between the second terminal TM2 and a reference potential terminal. One plate of the capacitor C is connected to the second terminal TM2, and the other plate is grounded to the reference potential terminal. The reference potential terminal is, for example, ground.

### <Neuromorphic Device>

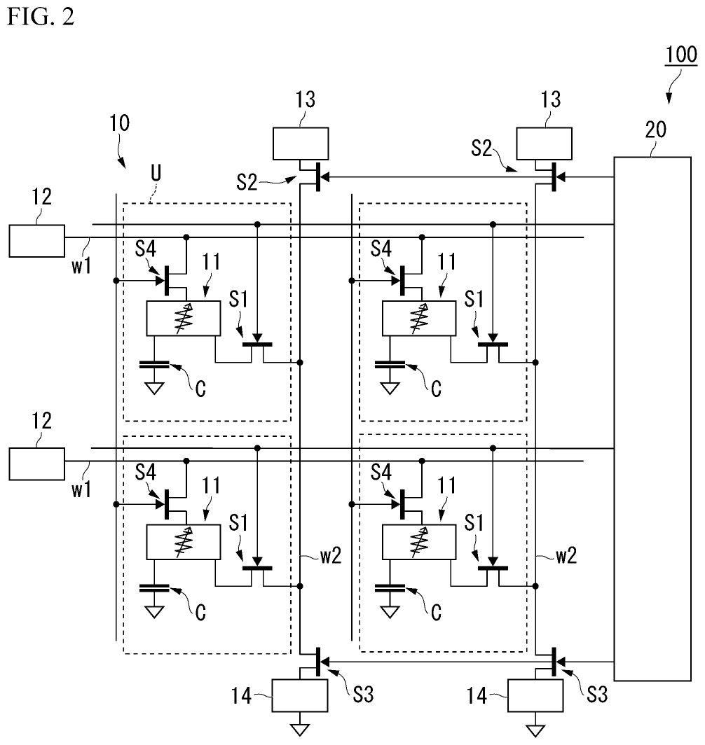

FIG. 2 is a diagram showing an example of a neuromorphic device 100 according to the first embodiment. The neuromorphic device 100 shown in FIG. 2 includes the smallest unit of the arithmetic circuit 1 shown in FIG. 1.

The neuromorphic device 100 shown in FIG. 2 includes an arithmetic circuit 10, an input circuit 12, a charging circuit 13, and an output circuit 14.

The arithmetic circuit 10 in the neuromorphic device 100 includes a plurality of the variable resistance elements 11, a plurality of the input lines w1, a plurality of the wirings w2, a plurality of the first switching elements S1, a plurality of the second switching elements S2, a plurality of the third switching elements S3, a plurality of the fourth switching elements S4, a plurality of the capacitors C, and the control unit 20.

The arithmetic circuit 10 has a plurality of units U including the input line w1, the variable resistance element 11, the capacitor C, the first switching element S1, and the fourth switching element S4. The plurality of units U are connected to one wiring w2. In the arithmetic circuit 10, the plurality of variable resistance elements 11 are arranged in a matrix form. The plurality of the variable resistance elements 11 are connected to one input line w1, and the plurality of the variable resistance elements 11 are also connected to one wiring w2.

The control unit 20 is connected to, for example, the first switching element S1, the second switching element S2, the third switching element S3, and the fourth switching element S4. The control unit 20 is connected to, for example, the gates of the first switching element S1, the second switching element S2, the third switching element S3, and the fourth switching element S4. The control unit 20 controls the on/off of the first switching element S1, the second switching element S2, the third switching element S3, and the fourth switching element S4. The control unit 20 is, for example, a control circuit unit provided on a semiconductor integrated circuit or a microcomputer. The control unit 20 may be another circuit or another device capable of controlling the arithmetic circuit 10.

The input circuit 12 is a circuit that generates an input signal input to the input line w1. The input circuit 12 is, for example, a neuron in a previous layer in the neuromorphic device.

The charging circuit 13 is a circuit for accumulating electric charge that generates a pulse current that changes a resistance of the variable resistance element 11 in the capacitor C. The charging circuit 13 is, for example, a power source. The charging circuit 13 may have a resistor between the power source and the second switching element S2. The charging speed of the capacitor C can be controlled by the resistor. The resistor may also be provided between the second switching element S2 and the first switching element S1.

The output circuit 14 is a circuit that outputs the electric charge accumulated in the capacitor C. The output circuit 14 is, for example, a detector. The output circuit 14 detects a spike signal.

### <Operation of Neuromorphic Device>

Next, the operation of the neuromorphic device 100 shown in FIG. 2 will be described. First, an output operation for outputting a spike signal from one unit U will be described.

First, the first switching element S1 is turned off, the second switching element S2 is turned off, and the fourth switching element S4 is turned on. The third switching element S3 may be turned on or off. In this state, an input signal is input from the input circuit 12. The input signal reaches the capacitor C through the fourth switching element S4 and the variable resistance element 11 to charge the capacitor C. The amount of electric charge accumulated in the capacitor C is determined by the resistance value of the variable resistance element 11 and the magnitude of the input signal. For example, in a case where the input signal is a signal indicating one of a plurality of input parameters in a spiking neural network, electric charge required to generate a spike signal corresponding to the input parameter and the resistance value of the variable resistance element 11 is accumulated in the capacitor C.

When the fourth switching element S4 is turned off after the electric charge is sufficiently accumulated in the capacitor C, the capacitor C maintains a state in which the electric charge is accumulated.

Next, the first switching element S1 is turned on. In a case where the third switching element S3 is off, the third switching element S3 is also turned on at the same time. When the first switching element S1 is turned on, the electric charge accumulated in the capacitor C flows to the output circuit 14. A signal corresponding to a discharge current is output from the capacitor C. In the spiking neural network, the signal is treated as the above-mentioned spike signal.

Here, FIG. 3 is a diagram showing an example of a waveform of a spike signal output from one unit U in the neuromorphic device 100. In a graph shown in FIG. 3, a vertical axis represents a voltage, and a horizontal axis represents an elapsed time from a timing indicated by the origin. The spike signal of FIG. 3 is a spike signal in a case where a resistance value of the variable resistance element 11 is 0.5 MΩ, and the input signal is a pulse signal having a pulse width of 10 ns, and a peak value of 0.5 V.

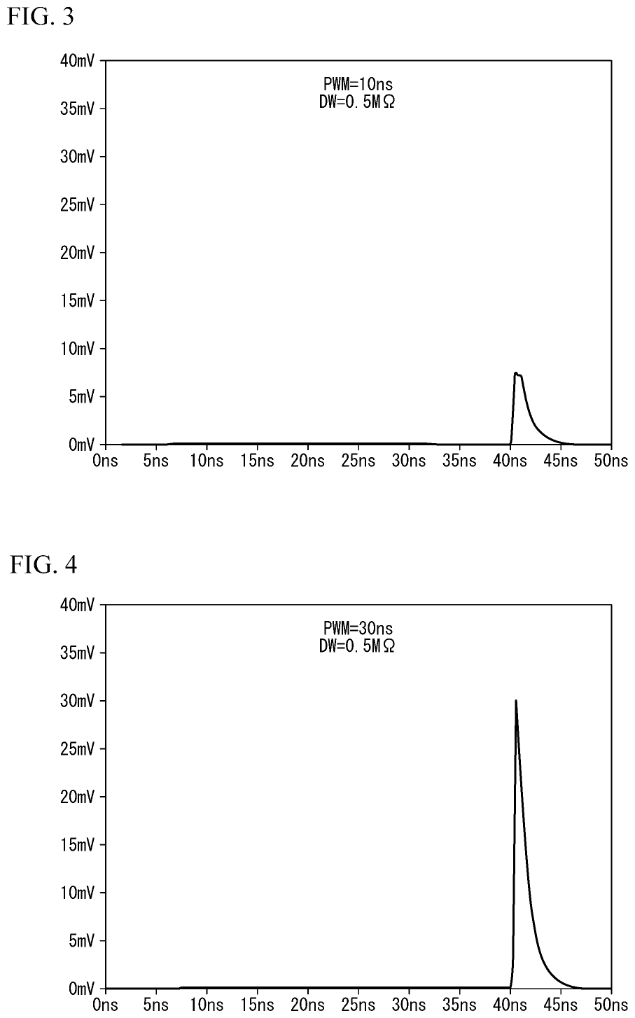

Furthermore, FIG. 4 is a diagram showing an example of the waveform of the spike signal output from one unit U in the neuromorphic device 100. In a graph shown in FIG. 4, a vertical axis represents a voltage, and a horizontal axis represents an elapsed time from the timing indicated by the origin. The spike signal of FIG. 4 is a spike signal in a case where a resistance value of the variable resistance element 11 is 0.5 MΩ, and the input signal is a pulse signal having a pulse width of 30 ns, and a peak value of 0.5 V.

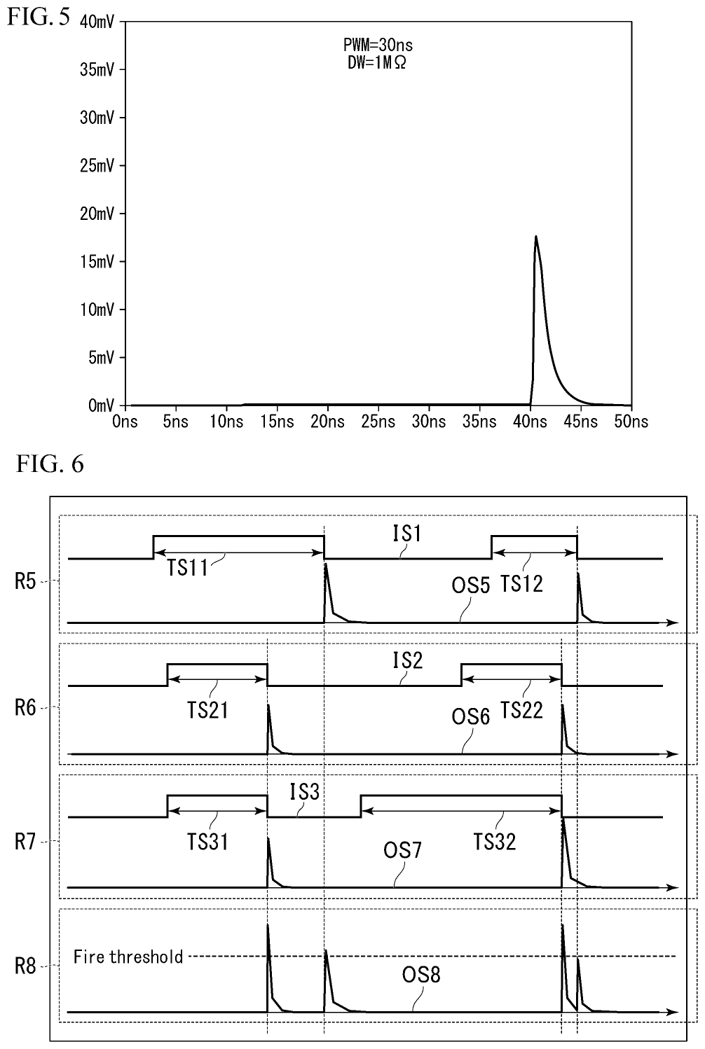

Furthermore, FIG. 5 is a diagram showing an example of the waveform of the spike signal output from one unit U in the neuromorphic device 100. In a graph shown in FIG. 5, a vertical axis represents a voltage, and a horizontal axis represents an elapsed time from the timing indicated by the origin. The spike signal of FIG. 5 is a spike signal in a case where a resistance value of the variable resistance element 11 is 1 MΩ, and the input signal is a pulse signal having a pulse width of 30 ns, and a peak value of 0.5 V.

As shown in FIGS. 3 to 5, the neuromorphic device 100 can output a signal corresponding to a discharge current of the capacitor C as a spike signal in a spiking neural network. Furthermore, as shown in FIGS. 3 to 5, an output spike signal changes according to the resistance value of the variable resistance element 11, and the pulse width, and the peak value of the input signal. A spike signal output from the third terminal TM3 is determined by the resistance value of the variable resistance element 11 and the input signal.

So far, an output operation of the spike signal from one unit U has been described. Next, a writing operation for changing the resistance value of the variable resistance element 11, which is one of parameters for changing the spike signal, will be described. The resistance value of the variable resistance element 11 changes, for example, according to a pulse current flowing between the second terminal TM2 and the third terminal TM3. Specifically, the resistance value of the variable resistance element 11 is a resistance value between the first terminal TM1 and the second terminal TM2 that affects the spike signal.

First, the first switching element S1 shown in FIG. 2 is turned on, the second switching element S2 is turned on, the third switching element S3 is turned off, and the fourth switching element S4 is turned off. In this case, the charging circuit 13 and the capacitor C are connected to charge the capacitor C.

In a case where the arithmetic circuit 10 does not have the fourth switching element 4, for example, a resistance between the first terminal TM1 and the second terminal TM2 of the variable resistance element 11 is greater than the resistance between the second terminal TM2 and the third terminal TM3. By increasing the resistance between the first terminal TM1 and the second terminal TM2, the electric charge charged in the capacitor C is prevented from being discharged to a side of the input circuit 12.

In addition, when a resistor is provided between the first switching element S1 and the second switching element S2 or between the second switching element S2 and the charging circuit 13, the capacitor C is slowly charged. When the charging speed of the capacitor C is high, a pulse current flows between the second terminal TM2 and the third terminal TM3. The pulse current flowing between the second terminal TM2 and the third terminal TM3 changes the resistance value of the variable resistance element 11. The resistance value of the variable resistance element 11 is controlled by discharging of the capacitor C described later. When the pulse current is generated when charging the capacitor C, the resistance value of the variable resistance element 11 fluctuates unexpectedly. By slowing the charging of the capacitor C, the pulse current is prevented from being generated when charging the capacitor C. Furthermore, a power source capable of controlling the charging speed may be used for the charging circuit 13.

When the first switching element S1 is turned off after the electric charge is sufficiently accumulated in the capacitor C, the capacitor C maintains the state in which the electric charge is accumulated. At this time, the second switching element S2 is also turned off.

Next, the first switching element S1 and the third switching element S3 are turned on. When the first switching element S1 is turned on, the electric charge accumulated in the capacitor C flows to the output circuit 14. At this time, a pulse current flows between the second terminal TM2 and the third terminal TM3. When the pulse current flows between the second terminal TM2 and the third terminal TM3, the resistance value of the variable resistance element 11 changes.

As described above, the neuromorphic device 100 can generate a spike signal to implement a spiking neural network using a three terminal variable resistance element. Furthermore, the resistance value of the variable resistance element 11 can also be changed using the discharge of the capacitor C to change a waveform of the output spike signal. In order to prevent the variable resistance element 11 from unexpectedly fluctuating due to a spike when the spike signal is generated, the resistance between the first terminal TM1 and the second terminal TM2 is preferably greater than the resistance between the second terminal TM2 and the third terminal TM3. As a result, the difference between the current value of the spike signal and the magnitude of a discharge pulse during the writing operation can be made to prevent an erroneous writing operation. The resistance between the first terminal TM1 and the second terminal TM2 is preferably 10 or more times, more preferably 100 or more times, than the resistance between the second terminal TM2 and the third terminal TM3.

As described above, one spike signal can be generated from one unit U. Furthermore, as shown in FIG. 2, in a case where a plurality of units U are connected to the wiring w2, the operation of the first switching element S1 of each unit U can be controlled by the control unit 20 to generate various spike signals. The operation of the first switching element S1 of each unit U may or may not be synchronized by the control unit 20. Hereinafter, three units connected to the same wiring w2 will be referred to as a first unit, a second unit, and a third unit.

FIG. 6 is a timing chart in a case where the operations of the first switching elements S1 of the plurality of units U connected to the wiring w2 are synchronized. The timing chart shows temporal changes in voltages at the first terminal TM1 and the third terminal TM3. A region R1 shown in FIG. 6 is a timing chart of the first unit. A region R2 shown in FIG. 6 is a timing chart of the second unit. A region R3 shown in FIG. 6 is a timing chart of the third unit. A region R4 shown in FIG. 6 is a timing chart showing a temporal change in the output voltage output to the output circuit 14.

Timing charts IS1, IS2, and IS3 each shows an example of a temporal change in a voltage at the first terminal TM1 of each unit. Furthermore, timing charts OS1, OS2, and OS3 each shows an example of a temporal change in a voltage at the third terminal TM3 of each unit. In addition, a timing chart OS4 shows an example of a temporal change in an output voltage output to the output circuit 14.

Periods TS11 and TS12 shown in FIG. 6 indicate periods during which an input signal is input to the first terminal TM1 of the first unit. As shown in FIG. 6, the period TS12 is a period subsequent to the period TS11.

Furthermore, a period TS21 and a period TS22 shown in FIG. 6 indicate periods during which the input signal is input to the first terminal TM1 of the second unit. As shown in FIG. 6, the period TS22 is a period subsequent to the period TS21.

A period TS31 and a period TS32 shown in FIG. 6 indicate periods during which the input signal is input to the first terminal TM1 of the third unit. As shown in FIG. 6, the period TS32 is a period subsequent to the period TS31.

Each of five timings of timing T1 to timing T5 shown in FIG. 6 is a timing at which a state of the first switching element S1 of each of the first unit to the third unit is changed from an OFF state to an ON state. The control unit 20 allows the first switching element S1 of each of the first unit to the third unit to be in an OFF state for a period until a predetermined time elapses at each of the five timings. The control unit 20 turns on the state of the first switching element S1 at a timing at which a predetermined time has elapsed. As a result, within the period, each of the first unit to the third unit outputs a spike signal corresponding to a discharge current of the capacitor C. A spike signal is output by making the resistance value of the wiring w2 lower than the resistance value of the variable resistance element 11 by about two to three orders of magnitude, even when the state of the first switching element S1 becomes an ON state while the input signal is input to the first terminal TM1.

As shown in FIG. 6, spike signals output from each of the first unit to the third unit are superimposed and output. A spike signal generated in the timing chart OS4 is a signal on which the spike signals output from each of the first unit to the third unit are superimposed.

That is, the neuromorphic device 100 can superimpose spike signals output from units U corresponding to each neuron in a spiking neural network, and perform processing according to a signal obtained by the superimposition. Here, “fire threshold” shown in the timing chart OS4 in FIG. 6 shows an example of a threshold value for the signal. For example, the neuromorphic device 100 can determine whether or not the magnitude of the signal exceeds the threshold value by a comparator or the like connected to a target output end. Then, the neuromorphic device 100 can perform processing according to the determination result.

FIG. 7 is a timing chart in a case where the operations of the first switching elements S1 of the plurality of units U connected to the wiring w2 are not partially synchronized. A region R5 shown in FIG. 7 is a timing chart of the first unit. A region R6 shown in FIG. 7 is a timing chart of the second unit. A region R7 shown in FIG. 7 is a timing chart of the third unit. A region R8 shown in FIG. 7 is a timing chart showing a temporal change in the output voltage output to the output circuit 14.

Timing charts IS1, IS2, and IS3 each shows an example of a temporal change in a voltage at the first terminal TM1 of each unit. Furthermore, timing charts OS5, OS6, and OS7 each shows an example of a temporal change in voltage at the third terminal TM3 of each unit. In addition, a timing chart OS8 shows an example of a temporal change in the output voltage output to the output circuit 14.

Here, in the timing chart OSS, a spike signal is output from the first unit at each of a timing at which the period TS11 ends and a timing at which the period TS12 ends. That is, this means that the control unit 20 controls the first switching element S1 of the first unit in synchronization with the timing of ending an input of the input signal to the first terminal TM1 of the first unit. Specifically, this means that the control unit 20 changes the state of the first switching element S1 from a first state to a second state at the timing.

In the timing chart OS6, a spike signal is also output from the second unit at each of a timing at which the period TS21 ends and a timing at which the period TS22 ends. Furthermore, in the timing chart OS7, a spike signal is also output from the third unit at each of a timing at which the period TS31 ends and a timing at which the period TS32 ends.

In this manner, the control unit 20 may also be configured to control the first switching element S1 of the arithmetic circuit 10 in synchronization with the timing of ending an input of the input signal to the first terminal TM1 of the arithmetic circuit 10 for each of the first unit to the third unit. In other words, the control unit 20 may also be configured to control the first switching element S1 of each of the first unit to the third unit not to be synchronized with one another. In this case, for example, the neuromorphic device 100 can superimpose a spike signal output from a unit U having high sensitivity to a certain information (or a certain input signal) in a spiking neural network to output the superimposed spike signal from an output end of a target transmission line. The superimposition of spike signals can be considered to be closer to processing performed in the human brain. Therefore, the neuromorphic device 100 can implement a spiking neural network that imitates the processing performed by the human brain at a higher level.

### <Specific Example of Variable Resistance Element>

Furthermore, a magnetic domain wall motion type magnetoresistance effect element, which is an example of the variable resistance element 11, will be described. The magnetoresistance effect element is an element that uses a giant magnetoresistance effect, a tunnel magnetoresistance effect, or the like as a magnetoresistance effect. The resistance value of the magnetoresistance effect element changes depending on a relationship between the magnetizations of two ferromagnetic layers included in the magnetoresistance effect element. The magnetoresistance effect element can, for example, change the relationship between the magnetizations of the two ferromagnetic layers by a spin polarization current. Then, the magnetic domain wall motion type magnetoresistance effect element is a magnetoresistance effect element capable of changing the relationship between the magnetizations of the two ferromagnetic layers by moving a magnetic domain wall in one of the two ferromagnetic layers by the spin polarization current.

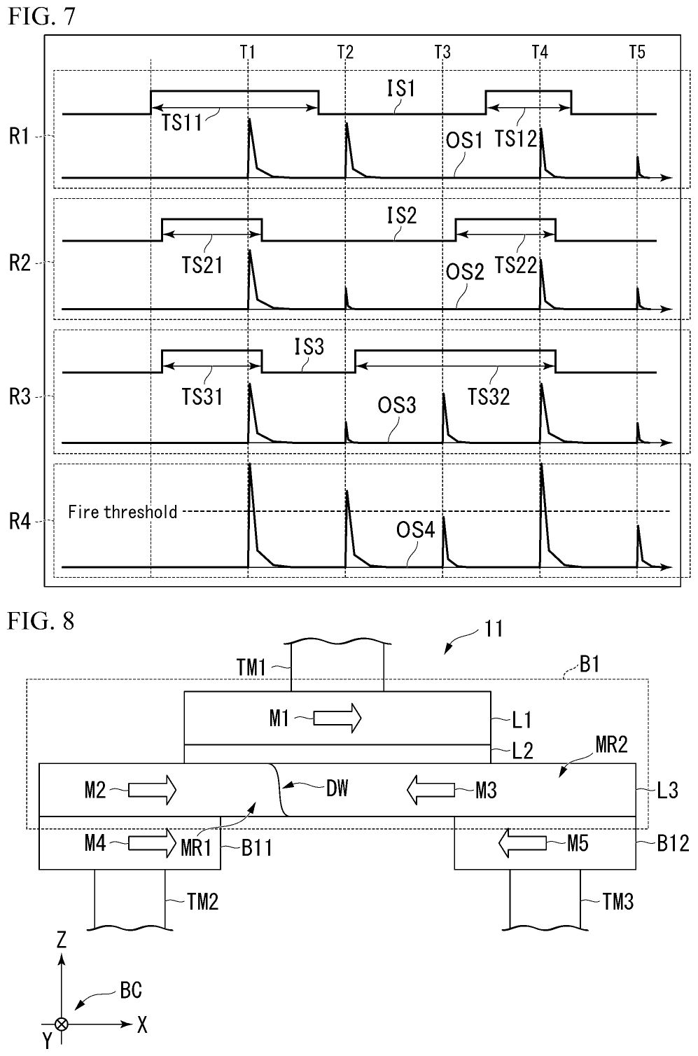

FIG. 8 is a diagram showing an example of a configuration of the variable resistance element 11. The variable resistance element 11 includes a variable resistance portion B1, a magnetization fixing portion B11, and a magnetization fixing portion B12 in addition to the three terminals including the first terminal TM1, the second terminal TM2, and the third terminal TM3.

The variable resistance portion B1 has two ferromagnetic layers. The resistance value of the variable resistance portion B1 changes depending on the relationship between the magnetizations of the two ferromagnetic layers. Specifically, the variable resistance portion B1 includes a ferromagnetic layer L1, a non-magnetic layer L2, and a magnetic recording layer L3. Hereinafter, as an example, a case where the shape of the magnetic recording layer L3 is a plate-shaped rectangular parallelepiped will be described. Furthermore, the shape of the magnetic recording layer L3 may also be another shape instead.

A three-dimensional coordinate system BC shown in FIG. 8 is a right-handed three-dimensional orthogonal coordinate system in which a longitudinal direction of the magnetic recording layer L3 and an X-axis direction coincide with each other, and a lateral direction of the magnetic recording layer L3 and a Y-axis direction coincide with each other. The variable resistance element 11 shown in FIG. 8 is the variable resistance element 11 when viewed in a negative direction of a Y-axis in the three-dimensional coordinate system BC. Hereinafter, for convenience of explanation, the positive direction of a Z-axis in the three-dimensional coordinate system BC will be referred to as the top or up direction, and the negative direction of the Z-axis will be referred to as the bottom or down direction.

In the variable resistance portion B1, the ferromagnetic layer L1, the non-magnetic layer L2, and the magnetic recording layer L3 are stacked in the order of the magnetic recording layer 12, the non-magnetic layer L2, and the ferromagnetic layer L1 from the bottom to top direction, as shown in FIG. 8.

The ferromagnetic layer L1 contains a ferromagnet. The ferromagnetic layer L1 is one of two ferromagnetic layers included in the variable resistance portion B1. In the ferromagnetic layer L1, a direction of magnetization is fixed. A direction M1 of arrow shown in FIG. 8 shows an example of a direction of magnetization fixed in the ferromagnetic layer L1. In the example shown in FIG. 8, the direction M1 coincides with a positive direction of an X-axis in the three-dimensional coordinate system BC.

In the example shown in FIG. 8, the above-mentioned first terminal TM1 is provided above the ferromagnetic layer L1. The first terminal TM1 is, for example, an electrode.

A ferromagnetic material constituting the ferromagnetic layer L1 is, for example, a metal selected from a group consisting of Cr, Mn, Co, Fe and Ni, an alloy containing one or more of these metals, an alloy or the like containing these metals and at least one or more elements of B, C, and N. The ferromagnetic layer L1 is, for example, Co—Fe, Co—Fe—B, or Ni—Fe.

The ferromagnetic layer L1 may contain a Heusler alloy. The Heusler alloy is a half metal and has a high spin polarizability. The Heusler alloy is an intermetallic compound having a chemical composition of XYZ or X₂YZ. X is a transition metal element or a noble metal element from the Co, Fe, Ni, or Cu group in the periodic table. Y is a transition metal from the Mn, V, Cr or Ti group or an element of X. Z is a typical element from Group III to Group V. The Heusler alloy is, for example, Co₂FeSi, Co₂FeGe, Co₂FeGa, Co₂MnSi, Co₂Mn₁₋ₐFeₐAl_{b}Si_{1-b}, or Co₂FeGe_{1-c}Ga_{c}.

In a case where the magnetization of the ferromagnetic layer L1 is oriented in a direction along an XY plane (the ferromagnetic layer L1 is an in-plane magnetization film), for example, the ferromagnetic layer L1 is NiFe. The XY plane is a plane parallel to both the X-axis and the Y-axis in the three-dimensional coordinate system BC. On the other hand, in a case where the magnetization of the ferromagnetic layer L1 is oriented in a direction along the Z-axis (the ferromagnetic layer L1 is a perpendicular magnetization film), for example, the ferromagnetic layer L1 is a Co/Ni stacked film or a Co/Pt stacked film. The Z-axis is a Z-axis in the three-dimensional coordinate system BC.

The ferromagnetic layer L1 may include a pinning layer made of an antiferromagnetic layer AF1 on a surface opposite to the non-magnetic layer L2. As a material of the antiferromagnetic layer AF1, IrMn, PtMn, or the like can be used.

A structure of the ferromagnetic layer L1 may be a synthetic structure. In the synthetic structure, a non-magnetic layer and a ferromagnetic layer are stacked on a surface of the ferromagnetic layer L1 opposite to the non-magnetic layer L2. The magnetization of the ferromagnetic layer L1 is strongly maintained by an antiferromagnetic coupling between the magnetizations of two ferromagnetic layers constituting the synthetic structure.

A known material can be used for the non-magnetic layer L2. For example, in a case where the non-magnetic layer L2 is made of an insulator (i.e., in a case where the non-magnetic layer L2 is a tunnel barrier layer), Al₂O₃, SiO₂, MgO, MgAl₂O₄, or the like can be used as a material thereof. As the non-magnetic layer L2, a material, or the like in which a part of Al, Si, and Mg of the above-mentioned material is replaced with Zn, Be, or the like may also be used. In a case where the non-magnetic layer L2 is made of metal, Cu, Au, Ag, or the like can be used as a material thereof. Moreover, in a case where the non-magnetic layer L2 is made of a semiconductor, Si, Ge, CuInSe₂, CuGaSe₂, Cu (In, Ga) Se₂, or the like can be used as a material thereof.

The magnetic recording layer L3 contains a ferromagnet. The magnetic recording layer L3 is the other of the two ferromagnetic layers included in the variable resistance portion B1. The magnetic recording layer L3 has a magnetic domain wall DW thereinside. The magnetic domain wall DW is a boundary between a magnetic domain MR1 and a magnetic domain MR2 in which the directions of magnetizations are opposite to each other in the magnetic recording layer L3. That is, the magnetic recording layer L3 has two magnetic domains, the magnetic domain MR1 and the magnetic domain MR2, thereinside. A direction M2 of arrow shown in FIG. 8 shows an example of a direction of magnetization in the magnetic domain MR1. In the example shown in FIG. 8, the direction M2 coincides with a positive direction of the X-axis in the three-dimensional coordinate system BC. A direction M3 of arrow shown in FIG. 8 shows an example of a direction of magnetization in the magnetic domain MR2. In the example shown in FIG. 8, the direction M3 coincides with a negative direction of the X-axis in the three-dimensional coordinate system BC.

The magnetization fixing portion B11 is provided below an end portion of a side of the magnetic domain MR1 on an end portion included in the magnetic recording layer L3. The above-mentioned second terminal TM2 is provided below the magnetization fixing portion B11. The second terminal TM2 is, for example, an electrode and via wiring.

As a ferromagnetic material constituting the magnetic recording layer L3, the same material as that of the ferromagnetic layer L1 can be used. The ferromagnetic material constituting the magnetic recording layer L3 may be a ferromagnetic material that is different from the ferromagnetic material constituting the ferromagnetic layer L1 among ferromagnetic materials capable of constituting the ferromagnetic layer L1. The magnetic recording layer L3 preferably has at least one element selected from a group consisting of, for example, Co, Ni, Pt, Pd, Gd, Tb, Mn, Ge, and Ga. Furthermore, in a case where perpendicular magnetization is used as the magnetic recording layer L3, for example, a stacked film of Co and Ni, a stacked film of Co and Pt, a stacked film of Co and Pd, a MnGa-based material, a GdCo-based material, and a TbCo-based material are used as the ferromagnetic material constituting the magnetic recording layer L3. A ferrimagnetic material such as the MnGa-based material, the GdCo-based material, and the TbCo-based material has a small saturation magnetization to reduce a threshold current required for moving the magnetic domain wall DW. Furthermore, the stacked film of Co and Ni, the stacked film of Co and Pt, and the stacked film of Co and Pd have a large coercive force to increase the stability of the element. In addition, the moving speed of the magnetic domain wall DW can be suppressed.

The magnetization fixing portion B11 contains a ferromagnet. In the magnetization fixing portion B11, a direction of magnetization is fixed. A direction M4 of arrow shown in FIG. 8 shows an example of a direction of magnetization (or a direction of the spin) fixed in the magnetization fixing portion B11. In the example shown in FIG. 8, the direction M4 coincides with a positive direction of the X-axis in the three-dimensional coordinate system BC.

A material constituting the magnetization fixing portion B11 may be any material capable of constituting the ferromagnetic layer L1. The magnetization fixing portion B11 may have a synthetic structure.

The magnetization fixing portion B12 is provided below an end portion of a side of the magnetic domain MR2 on an end portion included in the magnetic recording layer L3. The above-mentioned third terminal TM3 is provided below the magnetization fixing portion B12. The second terminal TM2 is, for example, an electrode and via wiring.

The magnetization fixing portion B12 contains a ferromagnet. In the magnetization fixing portion B12, the direction of magnetization is fixed. A direction M5 of arrow shown in FIG. 8 shows an example of the direction of magnetization fixed in the magnetization fixing portion B12. In the example shown in FIG. 8, the direction M5 coincides with a negative direction of the X-axis in the three-dimensional coordinate system BC.

A material constituting the magnetization fixing portion B12 may be any material capable of constituting the ferromagnetic layer L. The magnetization fixing portion B12 may have a synthetic structure.

In a case where a current flows from the second terminal TM2 to the third terminal TM3 through the magnetization fixing portion B11 and the magnetic recording layer L3 in this order, spin-polarized electrons flow in the same direction as the direction M5 of magnetization of the magnetization fixing portion B12 from the third terminal TM3 toward the second terminal TM2 in the magnetic recording layer L3. Specifically, in a case where a voltage is applied between the second terminal TM2 and the third terminal TM3 such that the potential of the third terminal TM3 is lower than the potential of the second terminal TM2, the electrons flow from a side of the third terminal TM3 toward a side of the second terminal TM2 in the magnetic recording layer L3.

On the contrary, in a case where a current flows from the third terminal TM3 to the second terminal TM2 through the magnetization fixing portion B12 and the magnetic recording layer L3 in this order, spin-polarized electrons flow in the same direction as the direction M4 of magnetization of the magnetization fixing portion B11 from the second terminal TM2 toward the third terminal TM3 in the magnetic recording layer L3. Specifically, in a case where a voltage is applied between the second terminal TM2 and the third terminal TM3 such that the potential of the third terminal TM3 is higher than the potential of the second terminal TM2, the electrons flow from a side of the second terminal TM2 toward a side of the third terminal TM3 in the magnetic recording layer L3.

In a case where a position of the magnetic domain wall DW is moved in the magnetic recording layer L3, the ratio of the volume occupied by the magnetic domain MR1 to the volume occupied by the magnetic domain MR2 changes inside the magnetic recording layer L3. In the example shown in FIG. 8, the direction M1 of magnetization of the ferromagnetic layer L1 is the same direction as the direction M2 of magnetization of the magnetic domain MR1, and is a direction opposite to the direction M3 of magnetization of the magnetic domain MR2.

In a case where the variable resistance portion B1 is viewed in a negative direction of the Z-axis in the three-dimensional coordinate system BC, an area in which the ferromagnetic layer L1 and the magnetic domain MR1 overlap becomes wider in a case where the magnetic domain wall DW moves in a positive direction of the X-axis in the three-dimensional coordinate system BC. As a result, in this case, the resistance value of the variable resistance element 11 becomes lower due to a magnetoresistance effect. On the other hand, the area becomes narrower in a case where the magnetic domain wall DW moves in a negative direction of the X-axis. As a result, in this case, the resistance value of the variable resistance element 11 becomes higher due to the magnetoresistance effect.

Here, as described above, in the variable resistance portion B1, the magnetic domain wall DW moves by allowing a pulse current to flow between the second terminal TM2 and the third terminal TM3.

That is, in a case where a current flows from the third terminal TM3 to the second terminal TM2, the magnetic domain MR1 extends in a direction of the magnetic domain MR2. As a result, the magnetic domain wall DW moves in the direction of the magnetic domain MR2. On the other hand, in this example, in a case where a current flows from the second terminal TM2 to the third terminal TM3, the magnetic domain MR2 extends in a direction of the magnetic domain MR1. As a result, the magnetic domain wall DW moves in the direction of the magnetic domain MR1.

In this manner, in the variable resistance portion B1, a position of the magnetic domain wall DW moves depending on a direction of a current flowing between the second terminal TM2 and the third terminal TM3 (i.e., the direction of a current flowing through the magnetic recording layer L3) and the intensity thereof to change the resistance value of the variable resistance element 11.

### <Configuration Method of Arithmetic Circuit>

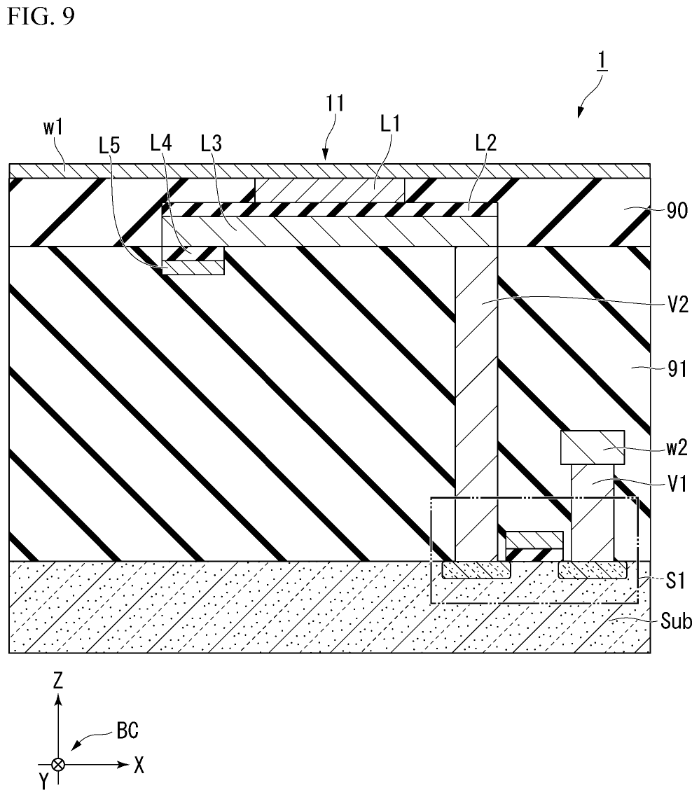

FIG. 9 is a diagram showing an example of the arithmetic circuit 1 built on a substrate Sub. As described above, the arithmetic circuit 1 includes, for example, the variable resistance element 11, the input line w1, the wiring w2, the first switching element S1, the second switching element S2, the third switching element S3, and the capacitor C.

The substrate Sub is, for example, a semiconductor substrate. The first switching element S1, the second switching element S2, the third switching element S3, and the fourth switching element S4 are disposed on the substrate Sub. The second switching element S2, the third switching element S3, and the fourth switching element S4 are not shown in the cross section, and are located at any position in the Y direction, for example.

The first switching element S1 is connected to the wiring w2 by, for example, a via wiring V1. Furthermore, the first switching element S1 is connected to the variable resistance element 11 by, for example, a via wiring V2. The wiring w2 extends in the Y direction, for example. The second switching element S2 and the third switching element S3 are connected to the wiring w2 at different positions in the Y direction of the wiring w2, for example, by a via wiring. The surroundings of the wiring w2, the first switching element S1, the second switching element S2, and the third switching element S3 are covered with an insulating layer 91.

The insulating layer 91 is an interlayer insulating film that insulates between the wirings of the multilayer wiring and between the elements. The insulating layer 91 is made of, for example, silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide. (ZrOₓ), or the like.

The variable resistance element 11 is connected to the first switching element S1 by, for example, the via wiring V2. The variable resistance element 11 is, for example, the above-mentioned magnetic domain wall motion element. The variable resistance element 11 is covered with an insulating layer 90. The insulating layer 90 is the same as the insulating layer 91.

The input line w1 is connected to the ferromagnetic layer L1 of the variable resistance element 11. An insulating layer L4 and a plate L5 are connected to the magnetic recording layer L3 of the variable resistance element 11. The insulating layer L4 and the plate L5 are connected to an end portion opposite to an end portion to which the via wiring V2 is connected in an X direction.

The insulating layer L4 functions as the capacitor C. One of two plates included in the capacitor C is a part of an outer circumferential portion of the variable resistance element 11. That is, an outer circumferential portion of the magnetic recording layer L3 facing the plate L5 functions as a plate of the capacitor C. When the outer circumferential portion of the magnetic recording layer L3 functions as the plate of the capacitor C, the number of components can be reduced, thereby suppressing an increase of manufacturing cost, and facilitating manufacturing. In addition, the neuromorphic device can be reduced in size.

### REFERENCE SIGNS LIST

1,10: Arithmetic circuit
11: Variable resistance element
12: Input circuit
13: Charging circuit
14: Output circuit
20: Control unit
100: Neuromorphic device
C: Capacitor
DW: Magnetic domain wall
L1: Ferromagnetic layer
L2: Non-magnetic layer
L3: Magnetic recording layer
L5: Plate
S1: First switching element
S2: Second switching element
S3: Third switching element
S4: Fourth switching element
TM1: First terminal
TM2: Second terminal
TM3: Third terminal
U: Unit
w1: Input line
w2: Wiring

1. An arithmetic circuit comprising:
a variable resistance element having three terminals of a first terminal, a second terminal, and a third terminal and configured such that a resistance value is variable;
an input line connected to the first terminal;
a capacitor connected to the second terminal and provided between the second terminal and a reference potential terminal;
a first switching element connected to the third terminal;
a wiring connected to the third terminal through the first switching element;
a second switching element connected to a first end of the wiring; and
a third switching element connected to a second end of the wiring.

2. The arithmetic circuit according to claim 1, wherein the variable resistance element is configured such that a resistance value between the first terminal and the third terminal varies based on a pulse current flowing between the second terminal and the third terminal.

3. The arithmetic circuit according to claim 1, further comprising:
a control unit configured to control the first switching element, the second switching element, and the third switching element, wherein
the control unit configured to turns off the first switching element while an input signal is input from the input line, and turns on the first switching element after electric charge is accumulated in the capacitor.

4. The arithmetic circuit according to claim 3, wherein
a signal output from the third terminal by turning on the first switching element is determined by a resistance value of the variable resistance element and the input signal.

5. The arithmetic circuit according to claim 1, further comprising:
a control unit configured to control the first switching element, the second switching element, and the third switching element, wherein
the control unit configured to turn on the first switching element and the second switching element,
the control unit configured to turn off the second switching element and to turn on the third switching element after the electric charge is accumulated in the capacitor.

6. The arithmetic circuit according to claim 1, further comprising:
a resistor between the first switching element and the second switching element.

7. The arithmetic circuit according to claim 1, further comprising:
a fourth switching element between the input line and the first terminal.

8. The arithmetic circuit according to claim 1, wherein
one of two plates of the capacitor is a part of an outer circumferential portion of the variable resistance element.

9. The arithmetic circuit according to claim 1, wherein
a plurality of units each including the input line, the variable resistance element, the capacitor, and the first switching element are connected to the wiring.

10. The arithmetic circuit according to claim 9, further comprising:
a control unit that controls the first switching element, the second switching element, and the third switching element, wherein
the control unit controls the first switching elements of at least a part of the plurality of units to be synchronized with one another.

11. The arithmetic circuit according to claim 9, further comprising:
a control unit that controls the first switching element, the second switching element, and the third switching element, wherein
the control unit controls the first switching elements of at least a part of the plurality of units not to be synchronized with one another.

12. The arithmetic circuit according to claim 1, wherein
the variable resistance element is a magnetic domain wall motion element, and
the magnetic domain wall motion element includes:
a magnetic recording layer connecting the second terminal and the third terminal;
a nonmagnetic layer stacked on the magnetic recording layer; and
a ferromagnetic layer sandwiching the non-magnetic layer with the magnetic recording layer.

13. A neuromorphic device comprising:
the arithmetic circuit according to claim 1;
an input circuit connected to the input line of the arithmetic circuit;
a charging circuit connected to the second switching element of the arithmetic circuit; and
an output circuit connected to the third switching element of the arithmetic circuit.
